(19) United States
(12) Patent Application Publication
(10) Pub. No.: US 2009/0206421 A1
(43) Pub. Date: Aug. 20, 2009

(54) ORGANIC LIGHT EMITTING DISPLAY AND MANUFACTURING METHOD THEREOF

(76) Inventors: Joon-Chul GOH, Hwaseong-si (KR); Chong-Chul Chai, Seoul (KR); Joon-Hoo Choi, Seoul (KR); Young-Soo Yoon, Suwon-si (KR)

Correspondence Address: Haynes and Boone, LLP;IP Section, 2323 Victory Avenue, SUITE 700, Dallas, TX, 75219, US

(21) Appl. No.: 12/247,964

(22) Filed: Oct. 8, 2008

(30) Foreign Application Priority Data
Feb. 20, 2008 (KR) 10-2008-0015113

(51) Int. Cl. H01L 29/78; H01L 21/00; H01J 1/62

(52) U.S. Cl. 257/412; 438/166; 313/504; 257/E29.255

(57) ABSTRACT

Disclosed are an organic light emitting display and a manufacturing method thereof. The organic light emitting display includes an organic light emitting section that generates a light, a first thin film transistor that drives the organic light emitting section and includes a first polysilicon layer and a first gate electrode formed below the first polysilicon layer, and a second thin film transistor connected to the first thin film transistor and includes a second polysilicon layer and a second gate electrode formed above the second polysilicon layer. The first and second polysilicon layers are formed on the same layer.

### CROSS-REFERENCE TO RELATED APPLICATION

This application claims priority to Korean Patent Application No. 2008-15113 filed on Feb. 20, 2008, the contents of which are herein incorporated by reference in their entirety.

### BACKGROUND

1. Field of the Invention

The present invention relates to an organic light emitting display capable of improving off-current characteristics thereof and a method of manufacturing the organic light emitting display.

2. Description of the Related Art

The importance of display apparatuses used to display information continues to increase in the modern society. Recently, various types of display apparatuses have been developed and utilized in various fields. Among the display apparatuses, an organic light emitting display (OLED) is spotlighted as being exemplary of a flat display apparatus due to its slim structure and superior color reproduction performance.

In general, the OLED displays an image by electrically exciting organic substances to emit light. The OLED includes a hole injection electrode (anode), an electron injection electrode (cathode), and an organic light emitting layer interposed between the anode and the cathode. In addition, the OLED includes a drive thin film transistor to drive the organic light emitting layer and a switch thin film transistor to control the drive thin film transistor.

In the OLED, a semiconductor layer of the drive thin film transistor is formed by using polysilicon through a laser irradiation method or a thermal treatment method. The thermal treatment method includes an solid phase crystallization (SPC) method.

However, the polysilicon formed through the SPC method represents inferior off-current characteristics, so the polysilicon is not suitable for the switch thin film transistor. For this reason, the drive thin film transistor is formed by using the polysilicon and the switch thin film transistor is formed by using amorphous silicon. However, the switch thin film transistor including the amorphous silicon represents problems in terms of high-speed operation.

### SUMMARY

Therefore, an exemplary embodiment of the present invention provides an organic light emitting display capable of improving off-current characteristics and ensuring high-speed operation.

Another exemplary embodiment of the present invention provides a method of manufacturing the organic light emitting display.

In an exemplary embodiment of the present invention, an organic light emitting display includes an organic light emitting section, a first thin film transistor and a second thin film transistor. The organic light emitting section generates a light. The first thin film transistor drives the organic light emitting section and includes a first polysilicon layer and a first gate electrode formed below the first polysilicon layer. The second thin film transistor is connected to the first thin film transistor and includes a second polysilicon layer and a second gate electrode formed above the second polysilicon layer. The first and second polysilicon layers are formed on the same layer.

The first thin film transistor may include a first source electrode and a first drain electrode formed on the first polysilicon layer, and the second thin film transistor may include a second source electrode and a second drain electrode formed on the second polysilicon layer.

The first thin film transistor may include a first insulating layer interposed between the first polysilicon layer and the first gate electrode. The first insulating layer includes one of oxide silicon and nitride silicon.

The second thin film transistor may include a second insulating layer interposed between the second polysilicon layer and the second gate electrode. The second insulating layer includes nitride silicon.

The second polysilicon layer may include a channel area overlapping the second gate electrode, a doping area overlapping the second source electrode and the second drain electrode, and an offset area interposed between the channel area and the doping area. The offset area has a width of about 2 μm to about 5 μm.

The first thin film transistor may be electrically connected to the second thin film transistor through a connection electrode.

The first thin film transistor may be electrically connected to the second thin film transistor through the second drain electrode connected to the first gate electrode.

The first gate electrode may overlap with the second polysilicon layer to block a light incident onto a bottom thereof.

The organic light emitting section may include a hole injection electrode, an electron injection electrode and an organic light emitting layer.

In another exemplary embodiment of the present invention, a method of manufacturing the organic light emitting display is provided as follows. A first gate pattern including a first gate electrode is formed on a substrate. First and second polysilicon layers are formed on the first gate pattern. Data patterns including first and second source electrodes and first and second drain electrodes are formed on first and second polysilicon layers, respectively. A second gate pattern including a second gate electrode is formed on the data pattern. A protective layer is formed on the second gate pattern. An organic light emitting section is formed on the protective layer.

A first insulating layer may be formed between the first gate pattern and the first and second polysilicon layers. In addition, a second insulating layer may be formed between the second gate pattern and the first and second polysilicon layers.

In order to form the first and second polysilicon layers, amorphous silicon layer is formed and impurities are implanted into the amorphous silicon layer. Then, the amorphous silicon layer is crystallized.

The second polysilicon layer may be divided into a channel area, an offset area and a doping area. The second gate electrode may overlap with the channel area of the second polysilicon layer. When forming the data pattern, a contact hole may be formed through the first insulating layer so that the second drain electrode is connected to the first gate electrode through the contact hole.

In order to form the organic light emitting section, a hole injection electrode connected to the first drain electrode is formed on the protective layer. Then, a pixel definition layer is formed on the protective layer such that the hole injection electrode is partially exposed. An organic light emitting layer is formed on the hole injection electrode. After that, an electron injection electrode is formed on the pixel definition layer and the organic light emitting layer.

When forming the light emitting section, a connection electrode may be formed to connect the first gate electrode to the second drain electrode. When forming the protective layer, a contact hole may be formed to partially expose the first drain electrode, the first gate electrode and the second drain electrode.

According to the above, the organic light emitting display may have improved off-current characteristics and ensure the high-speed operation thereof.

### BRIEF DESCRIPTION OF THE DRAWINGS

The above and other advantages of the present invention will become readily apparent by reference to the following detailed description when considered in conjunction with the accompanying drawings wherein:

FIG. 1 is an equivalent circuit view of an OLED according to an embodiment of the present invention;

FIG. 2 is a sectional view of an OLED according to a first embodiment of the present invention;

FIG. 3 is a graph showing a voltage-current characteristic of a second thin film transistor shown in FIG. 2;

FIG. 4 is a sectional view of an OLED according to a second embodiment of the present invention;

FIG. 5 is a sectional view of an OLED according to a third embodiment of the present invention;

FIG. 6 is a flowchart showing a method of manufacturing the OLED according to the first embodiment of the present invention; and

FIGS. 7A to 7F are sectional views showing a method of manufacturing the OLED shown in FIG. 6.

### DESCRIPTION OF THE EMBODIMENTS

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

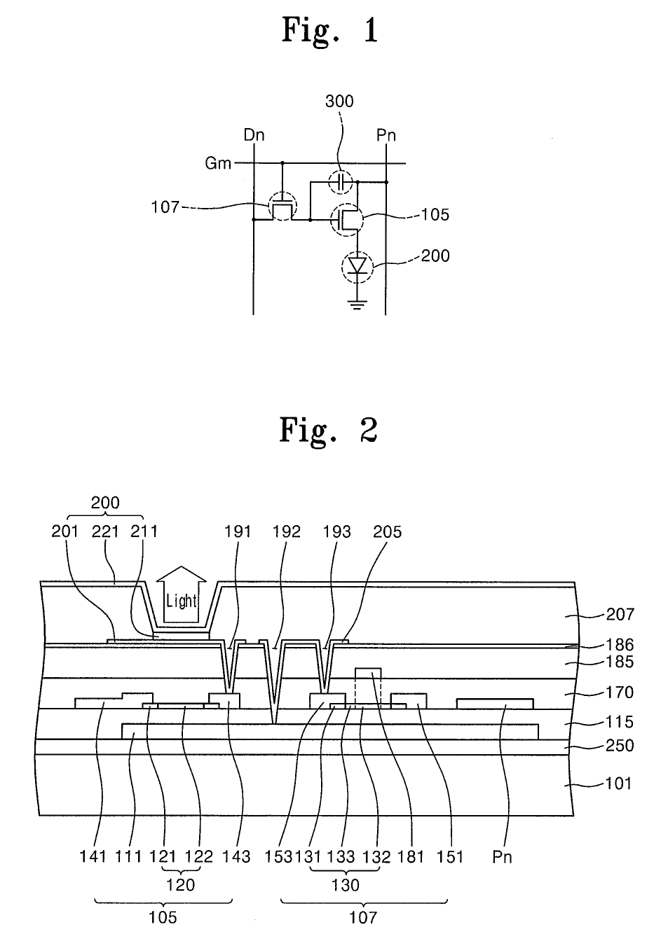

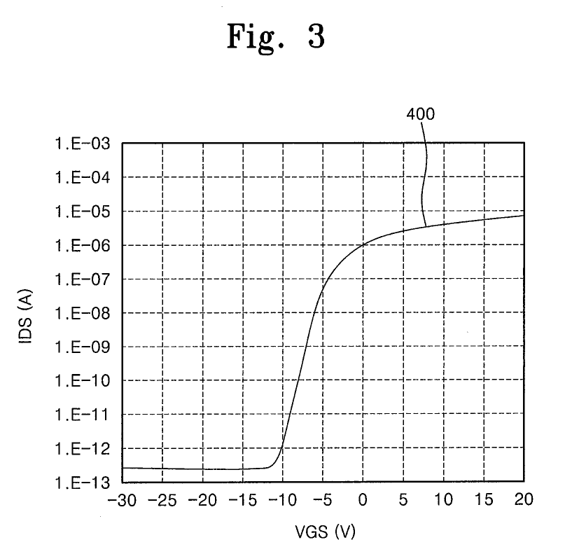

FIG. 1 is an equivalent circuit view of an OLED according to an embodiment of the present invention and FIG. 2 is a sectional view of the OLED according to a first embodiment of the present invention.

Referring to FIGS. 1 and 2, the OLED includes a plurality of signal lines Gm, Dn, and Pn, a first thin film transistor 105, a second thin film transistor 107, an organic light emitting section 200 and a capacitor 300 formed on a substrate 101.

The signal lines Gm, Dn, and Pn include an m^{th} gate line Gm aligned in the row direction to transfer gate signals, an n^{th} data line Dn aligned in the column direction to transfer data signals, and an n^{th} drive power line Pn aligned in the column direction to transfer driving power.

The first thin film transistor 105 is connected to the drive power line Pn and an output terminal of the second thin film transistor 107 and includes a first gate electrode 111, a first polysilicon layer 120, a first source electrode 141, and a first drain electrode 143. The first thin film transistor 105 serves as a drive transistor to convert voltage applied to the first gate electrode 111 and the first source electrode 141 into current. The first gate electrode 111 is aligned below the first polysilicon layer 120 so that the first thin film transistor 105 has a bottom gate structure. The first gate electrode 111 is insulated from the first polysilicon layer 120, the first source electrode 141 and the first drain electrode 143 by a first insulating layer 115. The first insulating layer 115 includes oxide silicon (SiOx) or nitride silicon (SiNx).

The first gate electrode 111 overlaps the second thin film transistor 107 to serve as a light blocking layer that blocks incident light.

The second thin film transistor 107 is connected to the gate line Gm and the data line Dn and includes a second gate electrode 181, a second polysilicon layer 130, a second source electrode 151, and a second drain electrode 153. The second thin film transistor 107 serves as a switch thin film transistor to switch data voltage applied to the data line to the first thin film transistor 105 according to the gate signal applied to the gate line. The second gate electrode 181 is aligned above the second polysilicon layer 130, so that the second thin film transistor 107 has a top gate structure. The second gate electrode 181 is insulated from the second polysilicon layer 130, the second source electrode 151 and the second drain electrode 153 by a second insulating layer 170. The second insulating layer 170 includes nitride silicon (SiNx).

The first and second polysilicon layers 120 and 130 are formed on the same layer through the solid phase crystallization method. The first and second polysilicon layers 120 and 130 include first and second doping areas 121 and 131, respectively. The first and second doping areas 121 and 131 may be formed by doping N-type impurities into amorphous silicon. The first and second doping areas 121 and 131 serve as ohmic contact areas to obtain ohmic contact among the first and second polysilicon layers 120 and 130, the first and second source electrodes 141 and 151 and the first and second drain electrodes 143 and 153.

The first polysilicon layer 120 is divided into the first doping area 121 and the first channel area 122. The second polysilicon layer 130 is divided into a second channel area 132 overlapping the second gate electrode 181, the second doping area 131, and an offset area 133 interposed between the second channel area 132 and the second doping area 131. The offset area 133 improves the off-current characteristics to enable the switch operation of the second thin film transistor 107. The offset area 133 may have a width of about 2 μm to about 5 μm. If the offset area 133 has a width less than about 2 μm, an alignment defect may occur in the second polysilicon layer 130 due to an error of a manufacturing process. In addition, if the offset area 133 has a width exceeding about 5 μm, the on-current characteristics may be degraded.

Meanwhile, the first and second thin film transistors 105 and 107 are connected to each other through a connection electrode 205. The connection electrode 205 is formed on a protective layer 185 and a planar layer 186. In addition, the connection electrode 205 electrically connects the first gate electrode 111 to the second drain electrode 153 through the second and third contact holes 192 and 193. The connection electrode 205 may include transparent conductive material. For instance, the connection electrode 205 may include one of indium tin oxide (ITO), indium zinc oxide (IZO) and indium tin zinc oxide (ITZO).

The organic light emitting section 200 is formed on the protective layer 185 and the planar layer 186, and includes a hole injection electrode 201 connected to the first thin film transistor 105, an electron injection electrode 221 corresponding to the hole injection electrode 201 and an organic light emitting layer 211 interposed between the hole injection electrode 201 and the electron injection electrode 221. The hole injection electrode 201 is connected to the first drain electrode 143 through a first contact hole 191. The organic light emitting layer 211 is filled in a pattern part of a pixel definition layer 207 that exposes the hole injection electrode 201 and includes a hole transmission layer, a light emitting layer and an electron transmission layer. The electron injection electrode 221 is formed on the organic light emitting section 211 and the pixel definition layer 207 by using conductive material.

The organic light emitting section 200 emits light in one direction. The hole injection electrode 201 and the electron injection electrode 221 may be fabricated using various materials depending on the light emission direction of the organic light emitting section 200. For instance, if the organic light emitting section 200 emits light in the forward direction, the hole injection electrode 201 is fabricated using reflective conductive material and the electron injection electrode 221 is fabricated using transparent conductive material. In contrast, if the organic light emitting section 200 emits light in the rearward direction, the hole injection electrode 201 is fabricated using transparent conductive material and the electron injection electrode 221 is fabricated using reflective conductive material.

One electrode of the capacitor 300 is connected to the drive power line Pn and the other electrode of the capacitor 300 is connected to both the first drain electrode 143 and the second gate electrode 181. The capacitor 300 may be formed by overlapping the drive power line Pn with the first gate electrode 111. When the gate signal has been supplied to the m^{th} gate line Gm, the capacitor 300 is charged with the gate signal until a new gate signal is applied to the m^{th} gate line Gm, thereby allowing the organic light emitting section 200 to continuously emit light.

Meanwhile, a buffer layer 250 may be formed below the first gate electrode 111. The buffer layer 250 is formed over the whole area of the substrate 101. The buffer layer 250 may include oxide silicon.

FIG. 3 is a graph showing a voltage-current characteristic of the second thin film transistor shown in FIG. 2. In FIG. 3, the X-axis represents voltage and the Y-axis represents current.

The second thin film transistor exhibits a voltage-current (VGS-IDS) characteristic curve 400 as shown in FIG. 3 in order to serve as a switch device. In the second thin film transistor, a width and a length of a channel of the second polysilicon layer are about 5 μm, respectively, and a size of the offset area is about 2 μm. In addition, the second thin film transistor is insulated from the second gate electrode and the second polysilicon layer by the second insulating layer including nitride silicon.

The channel width of the second polysilicon layer of the second thin film transistor is smaller than that of the bottom gate structure. According to the characteristic curve 400, threshold voltage Vth becomes high and off-current is suitable for the switch operation. At this time, repulsive force is applied to electrons of the offset area due to negative voltage of the gate electrode, so that concentration of electrons in the second thin film transistor may be lowered. Since the concentration of electrons may be lowered, the second thin film transistor may reduce leakage current together with the offset area, thereby lowering the level of off-current.

In a compensation circuit structure requiring many switch devices for each pixel, the second thin film transistor may be formed in a smaller area due to the second polysilicon layer. In detail, mobility of the second thin film transistor is improved so that the second thin film transistor may serve as a switch device even if the second thin film transistor has a smaller area. Thus, the second thin film transistor may reduce the whole area for the switch device in the compensation circuit structure. Accordingly, the second thin film transistor may improve the aperture ratio in the bottom emission type OLED.

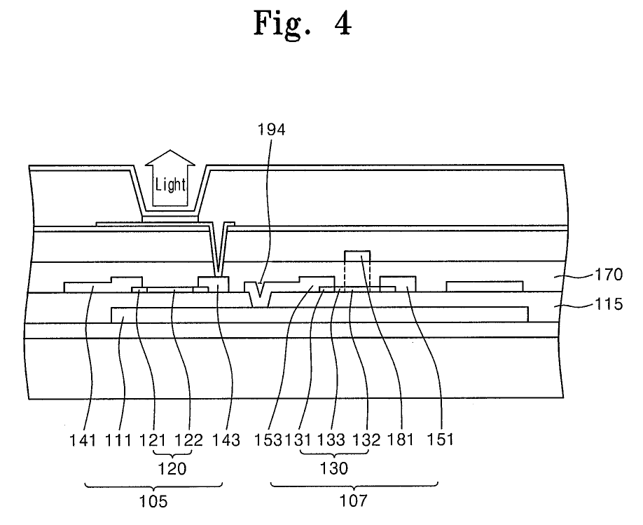

FIG. 4 is a sectional view of an OLED according to the second embodiment of the present invention.

Referring to FIGS. 1 and 4, the OLED includes first and second thin film transistors 105 and 107 that are directly connected to each other.

The first and second thin film transistors 105 and 107 include first and second gate electrodes 111 and 181, first and second polysilicon layers 120 and 130, first and second source electrodes 141 and 151, and first and second drain electrodes 143 and 153, respectively. The first and second gate electrodes 111 and 181 are insulated by first and second insulating layers 115 and 170, respectively.

The second drain electrode 153 of the second thin film transistor 107 is connected to the first gate electrode 111 of the first thin film transistor 105 through a fourth contact hole 194. The first and second thin film transistors 105 and 107 may be directly connected to each other without interposing the connection electrode therebetween.

Detailed description of the elements identical to those of the OLED shown in FIG. 2 will be omitted in order to avoid redundancy.

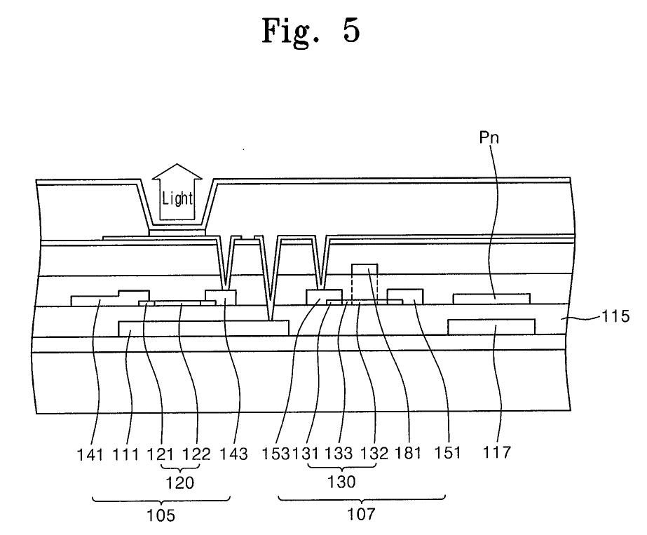

FIG. 5 is a sectional view of an OLED according to the third embodiment of the present invention.

Referring to FIGS. 1 and 5, the OLED includes a light blocking layer provided below the second thin film transistor 107.

The first thin film transistor 105 has a bottom gate structure, in which the first gate electrode 111 is positioned below the first polysilicon layer 120. The first gate electrode 111 may not overlap the second polysilicon layer 130 of the second thin film transistor 107. The second thin film transistor 107 having the above structure can prevent the characteristic degradation of the second polysilicon layer 130 caused by the first gate electrode.

The storage electrode 117 is positioned on the same layer as the first gate electrode 111. The first storage electrode 117 overlaps the drive power line Pn while interposing the first insulating layer 115 therebetween.

Detailed description of the elements identical to those of the OLED shown in FIG. 2 will be omitted in order to avoid redundancy.

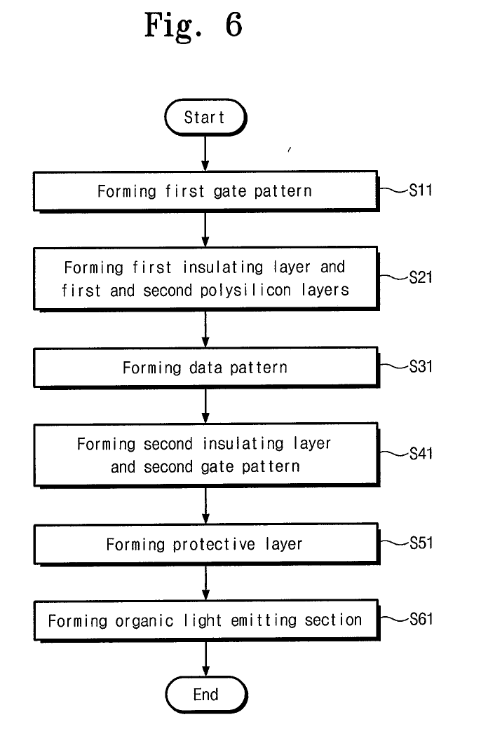

FIG. 6 is a flowchart showing a method of manufacturing the OLED according to the first embodiment of the present invention.

Referring to FIG. 6, the method of manufacturing the OLED includes forming a first gate pattern (S11), forming a first insulating layer and first and second polysilicon layers (S21), forming a data pattern (S31), forming a second insulating layer and a second gate pattern (S41), forming a protective layer (S51), and forming an organic light emitting section (S61).

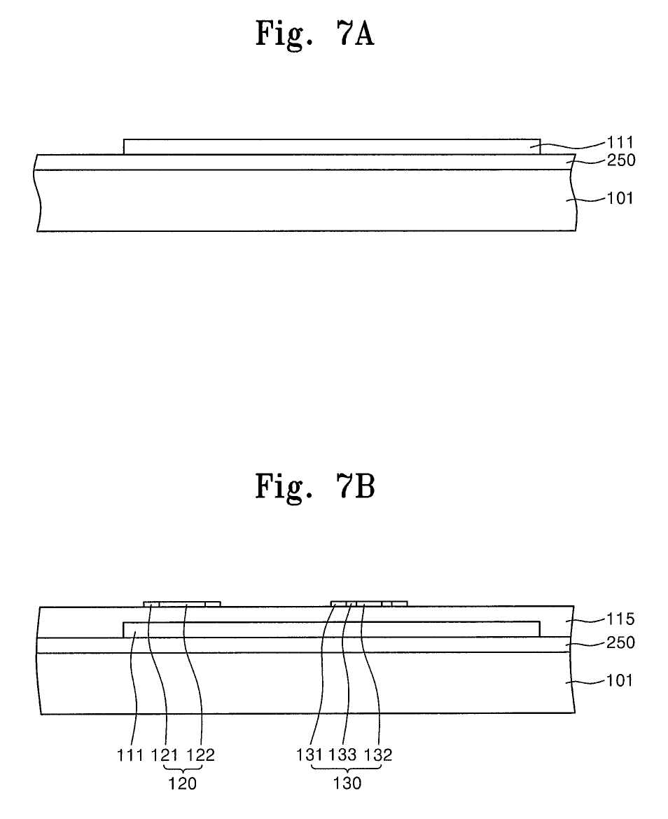

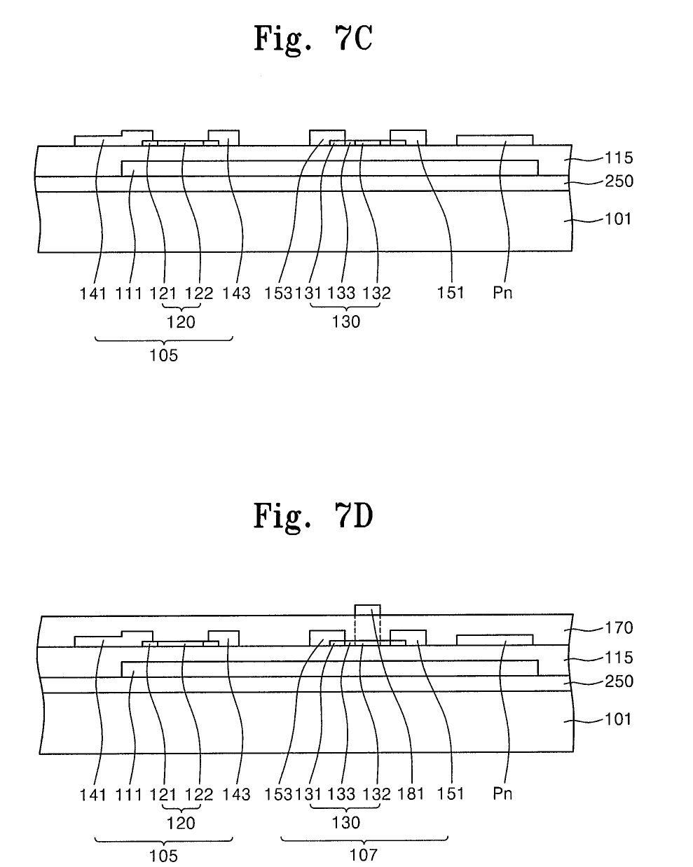

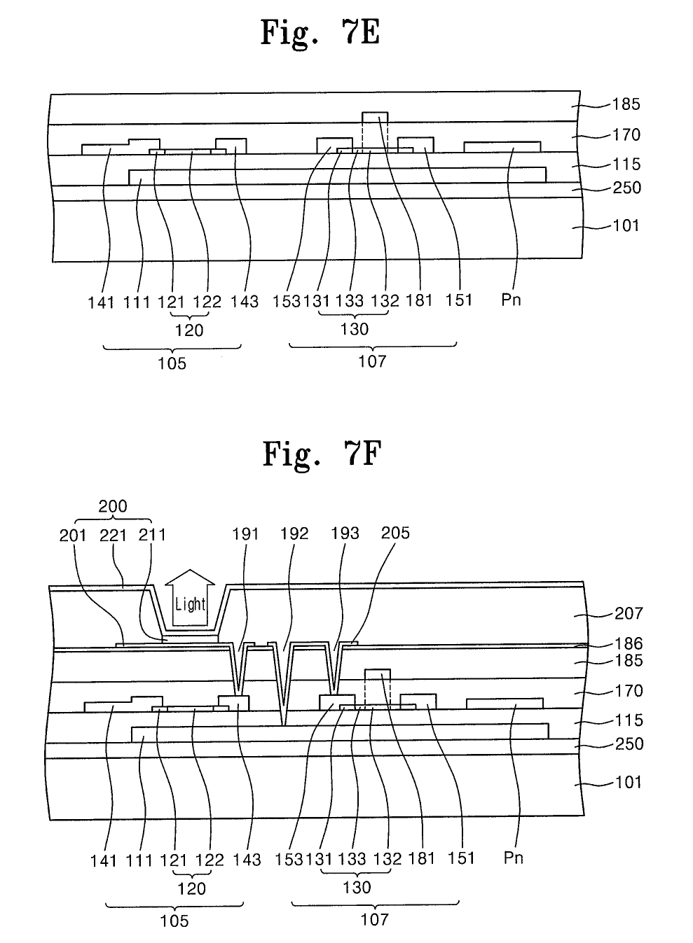

FIGS. 7A to 7F are sectional views showing the method of manufacturing the OLED shown in FIG. 6.

In order to form the first gate pattern (S11), a gate metal is deposited on the substrate 101 and then a first gate line (not shown) and the first gate electrode 111 are formed through the photo and etching processes (see, FIG. 7A). The buffer layer 250 is previously formed on the entire surface of the substrate 101 by using oxide silicon. The first gate pattern may be formed on the buffer layer 250 deposited on the substrate 101.

Then, the first insulating layer 115 is formed on the first gate electrode 111 by depositing oxide silicon on the first gate electrode 111 (see, FIG. 7B). After that, amorphous silicon is deposited on the first insulating layer 115. Then, n-type impurities are implanted into the amorphous silicon, thereby forming first and second doping areas 121 and 131. Subsequently, the amorphous silicon is patterned through photo and etching processes. Then, the amorphous silicon is crystallized through a solid phase crystallization process, thereby forming the first and second polysilicon layers 120 and 130 (S21).

After that, in order to form the data pattern (S31), a data metal is deposited on the first and second polysilicon layers 120 and 130 and photo and etching processes are performed relative to the data metal, thereby forming the data line (not shown), the drive power line Pn, the first and second source electrodes 141 and 151, and the first and second drain electrodes 143 and 153 (see, FIG. 7C). The first source electrode 141 and the first drain electrode 143 are connected to the first doping area 121 of the first polysilicon layer 120. In addition, the second source electrode 151 and the second drain electrode 153 are connected to the second doping area 131 of the second polysilicon layer 130.

Then, nitride silicon is deposited on the entire surface of the data pattern formed on the substrate 101, thereby forming the second insulating layer (S41) (see, FIG. 7D). After that, a gate metal is deposited on the second insulating layer 170, and then the photo and etching processes are performed relative to the gate metal to form the second gate electrode 181. The second polysilicon layer 130 is divided into the second channel area 132 and the offset area 133 by the second gate electrode 181. For instance, the second gate electrode 181 overlaps the second polysilicon layer 130 while being spaced apart from the second doping area 131 by a distance of about 2 μm to about 5 μm.

In order to form the protective layer (S51), nitride silicon is deposited on the second gate electrode 181 and the second insulating layer 170, thereby forming the protective layer 185 (see, FIG. 7E). In addition, the planar layer 186 may be formed on the protective layer 185 in order to planarize the protective layer 185. The planar layer 186 can be formed by coating organic substance on the protective layer 185. Then, first to third contact holes 191, 192, and 193 are formed through the planar layer 186 and the protective layer 185. The first drain electrode 143, the first gate electrode 111 and the second drain electrode 153 are partially exposed through the first to third contact holes 191, 192 and 193. To this end, the first to third contact holes 191, 192 and 193 are formed by selectively etching the planar layer 186, the protective layer 185, the second insulating layer 170 and the first insulating layer 115.

The first to third contact holes 191, 192 and 193 can be formed by simultaneously or sequentially etching the planar layer 186 and the protective layer 185.

Then, the hole injection electrode 201, which is connected to the first drain electrode 143 through the first contact hole 191, and the connection electrode 205, which is connected to the first gate electrode 111 and the second drain electrode 153 through the second contact hole 192, are formed (S61) (see, FIG. 7F). The hole injection electrode 201 and the connection electrode 205 may be formed by using a transparent conductive material or a reflective conductive material depending on the light emission direction of the organic light emitting section 200.

After that, the pixel definition layer 207 is formed on the hole injection electrode 201 and the connection electrode 205. The pixel definition layer 207 is provided with an opening formed therethrough to partially expose the hole injection electrode 201. The pixel definition layer 207 includes inorganic or organic substance, so that the pixel definition layer 207 may have transparent property or opaque property. Then, organic light emitting material is implanted onto the hole injection electrode 201, thereby forming the organic light emitting layer 211. Finally, the electron injection electrode 221 is formed on the pixel definition layer 207 and the organic light emitting layer 211. The electron injection electrode 221 may be formed using the transparent conductive material or the reflective conductive material depending on the light emission direction of the organic light emitting section 200.

Meanwhile, according to the second embodiment of the present invention, in forming the data pattern, a fourth contact hole 194 (see, FIG. 4) is formed through the first insulating layer 115 such that the second drain electrode 153 is connected to the first gate electrode 111 through the fourth contact hole 184. In addition, when forming the protective layer and the organic light emitting section, the first contact hole 191 and the hole injection electrode 201 are exclusively formed. That is, according to the second embodiment of the present invention, the first gate electrode 111 is directly connected to the second drain electrode 153, so that the connection electrode 205 is not necessary.

According to the above, the off-current characteristics may be improved and the high-speed operation may be ensured.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An organic light emitting display comprising:
an organic light emitting section that generates a light;
a first thin film transistor that drives the organic light emitting section and comprises a first polysilicon layer and a first gate electrode formed below the first polysilicon layer; and
a second thin film transistor connected to the first thin film transistor and comprises a second polysilicon layer and a second gate electrode formed above the second polysilicon layer, and
wherein the first and second polysilicon layers are formed on a same layer.

2. The organic light emitting display as claimed in claim 1, wherein the first thin film transistor further comprises a first source electrode and a first drain electrode formed on the first polysilicon layer, and the second thin film transistor further comprises a second source electrode and a second drain electrode formed on the second polysilicon layer.

3. The organic light emitting display as claimed in claim 2, wherein the first thin film transistor further comprises a first insulating layer interposed between the first polysilicon layer and the first gate electrode.

4. The organic light emitting display as claimed in claim 2, wherein the second thin film transistor further comprises a second insulating layer interposed between the second polysilicon layer and the second gate electrode.

5. The organic light emitting display as claimed in claim 2, wherein the second polysilicon layer comprises a channel area overlapping the second gate electrode, a doping area overlapping the second source electrode and the second drain electrode, and an offset area interposed between the channel area and the doping area.

6. The organic light emitting display as claimed in claim 2, wherein the offset area has a width of about 2 μm to about 5 μm.

7. The organic light emitting display as claimed in claim 2, further comprising a protective layer formed on the first and the second thin film transistor and a connection electrode formed on the protective layer,
wherein the first thin film transistor is electrically connected to the second thin film transistor through the connection electrode.

8. The organic light emitting display as claimed in claim 2, wherein the first gate electrode is connected to the second drain electrode so that the first thin film transistor is electrically connected to the second thin film transistor.

9. The organic light emitting display as claimed in claim 1, wherein the first gate electrode overlaps the second polysilicon layer to block a light incident onto a bottom thereof.

10. The organic light emitting display as claimed in claim 1, wherein the organic light emitting section comprises a hole injection electrode, an electron injection electrode and an organic light emitting layer.

11. A method of manufacturing an organic light emitting display, the method comprising:
forming a first gate pattern comprising a first gate electrode on a substrate;
forming first and second polysilicon layers on the first gate pattern;
forming data patterns comprising first and second source electrodes and first and second drain electrodes on first and second polysilicon layers, respectively;
forming a second gate pattern comprising a second gate electrode on the data pattern;
forming a protective layer on the second gate pattern; and
forming an organic light emitting section on the protective layer.

12. The method as claimed in claim 11, further comprising forming a first insulating layer between the first gate pattern and the first polysilicon layer and between the first gate pattern and the second polysilicon layer.

13. The method as claimed in claim 12, further comprising forming a second insulating layer between the second gate pattern and the first polysilicon layer and between the second gate pattern and the second polysilicon layer.

14. The method as claimed in claim 11, wherein the forming of the first and second polysilicon layers comprises:
forming amorphous silicon layer;
implanting impurities into the amorphous silicon layer; and
crystallizing the amorphous silicon layer.

15. The method as claimed in claim 14, wherein the second polysilicon layer is divided into a channel area, an offset area and a doping area.

16. The method as claimed in claim 15, wherein the second gate electrode overlaps the channel area of the second polysilicon layer.

17. The method as claimed in claim 11, wherein, when forming the data pattern, a contact hole is formed through the first insulating layer so that the second drain electrode is connected to the first gate electrode through the contact hole.

18. The method as claimed in claim 11, wherein the forming of the organic light emitting section comprises:
forming a hole injection electrode connected to the first drain electrode on the protective layer;
forming a pixel definition layer on the protective layer such that the hole injection electrode is partially exposed;
forming an organic light emitting layer on the hole injection electrode; and
forming an electron injection electrode on the pixel definition layer and the organic light emitting layer.

19. The method as claimed in claim 18, wherein the forming of the hole injection electrode comprises forming a connection electrode to connect the first gate electrode to the second drain electrode.

20. The method as claimed in claim 19, wherein, when forming the protective layer, a contact hole is formed to partially expose the first drain electrode, the first gate electrode and the second drain electrode.
